(19) United States
(12) Patent Application Publication
(10) Pub. No.: US 2015/0240349 A1
(43) Pub. Date: Aug. 27, 2015

(54) MAGNETRON SPUTTERING DEVICE AND METHOD OF FABRICATING THIN FILM USING MAGNETRON SPUTTERING DEVICE

(71) Applicant: Avago Technologies General IP (Singapore) Pte. Ltd., Singapore (SG)

(72) Inventors: Kevin J. Grannen, Thornton, CO (US); Chris Feng, Fort Collins, CO (US); Ivan Ionash, Fort Collins, CO (US); Phil Nikkel, Loveland, CO (US); Tangshiun Yeh, Fort Collins, CO (US); John Choy, Westminster, CO (US)

(73) Assignee: Avago Technologies General IP (Singapore) Pte. Ltd., Singapore (SG)

(21) Appl. No.: 14/191,995

(22) Filed: Feb. 27, 2014

(51) Int. Cl. C23C 14/35; H01J 37/34

(52) U.S. Cl. CPC C23C 14/35; H01J 37/3405

(57) ABSTRACT

A method is provided for depositing a thin film of material on a substrate. The method includes providing the substrate on a cathode and a target on an anode in a reaction chamber of a magnetron sputtering device, generating a magnetic field using an enhanced magnetron including an upper base plate to generate an upper magnetic field having a field strength of about 205 gauss and a lower base plate to generate a lower magnetic field having a field strength of about −215 gauss to about −370 gauss, injecting sputtering gas at low pressure into the reaction chamber, and applying power across the anode and cathode to create plasma. Ions from the plasma sputter atoms of at least one element from the target, which are deposited on the substrate to form the thin film. Power density of the power is in a range of about 20 W/cm² to about 60 W/cm².

### BACKGROUND

Transducers generally convert electrical signals to mechanical signals or vibrations, and/or mechanical signals or vibrations to electrical signals. Acoustic transducers, in particular, convert electrical signals to acoustic signals (sound waves) and convert received acoustic waves to electrical signals via inverse and direct piezoelectric effect. Acoustic transducers generally include acoustic resonators, such as surface acoustic wave (SAW) resonators and bulk acoustic wave (BAW) resonators, and may be used in a wide variety of electronic applications, such as cellular telephones, personal digital assistants (PDAs), electronic gaming devices, laptop computers and other portable communications devices. For example, BAW resonators include thin film bulk acoustic resonators (FBARs), which include acoustic stacks formed over a substrate cavity, and solidly mounted resonators (SMRs), which include acoustic stacks formed over an acoustic reflector (e.g., Bragg mirror). The BAW resonators may be used for electrical filters and voltage transformers, for example.

Generally, an acoustic resonator has a layer of piezoelectric material between two conductive plates (electrodes), which may be formed on a thin membrane. The piezoelectric material may be a thin film of various materials, such as aluminum nitride (AlN), zinc oxide (ZnO), or lead zirconate titanate (PZT), for example. Piezoelectric thin films made of AlN are advantageous since they generally maintain piezoelectric properties at high temperature (e.g., above 400° C.). However, AlN has a lower piezoelectric coupling coefficient d₃₃ and a lower electromechanical coupling coefficient Kt² than both ZnO and PZT, for example.

An AlN thin film may be deposited with various specific crystal orientations, including a wurtzite (0001) B4 structure, which consists of a hexagonal crystal structure with alternating layers of aluminum (Al) and nitrogen (N), and a zincblende structure, which consists of a symmetric structure of Al and N atoms, for example. FIG. 1 is a perspective view of an illustrative model of the common wurtzite structure. Due to the nature of the Al—N bonding in the wurtzite structure, electric field polarization is present in the AlN crystal, resulting in the piezoelectric properties of the AlN thin film. To exploit this polarization and the corresponding piezoelectric effect, one must synthesize the AlN with a specific crystal orientation.

Referring to FIG. 1, the a-axis and the b-axis are in the plane of the hexagon at the top, while the c-axis is parallel to the sides of the crystal structure. For AlN, the piezoelectric coefficient d₃₃ along the c-axis is about 3.9 pm/V and the electromechanical coupling coefficient Kt² is about 6.0, for example. Generally, higher piezoelectric coupling coefficient d₃₃ and electromechanical coupling coefficient Kt² are desirable, since less material is required to provide the same piezoelectric effect. In order to improve the value of the piezoelectric coefficient d₃₃ and/or the electromechanical coupling coefficient Kt², some of the Al atoms may be replaced with a different metallic element, which may be referred to as “doping.” For example, past efforts included disturbing the stoichiometric purity of the AlN crystal lattice by adding a rare earth element, such as scandium (Sc) (e.g., in amounts greater than 0.5 atomic percent) or erbium (Er) (e.g., in amounts less than 1.5 atomic percent) in place of some Al atoms, but not both.

One side effect of the doping with scandium, for example, is increased tensile stress in the resulting (ScAlN) thin film. This tensile stress increases the electromechanical coupling coefficient Kt² in the acoustic resonator fabricated using the ScAlN thin film. For example, AlN thin film doped with about 5 atomic percent scandium has a significantly increased sensitivity of electromechanical coupling coefficient Kt² to thin film stress than that for undoped AlN. For example, the electromechanical coupling coefficient Kt² to thin film stress of the ScAlN thin film may have a positive slope value of about 0.0006, which is about 50 percent higher than a positive slope value of the electromechanical coupling coefficient Kt² to thin film stress of AlN thin film. Another side-effect of doping with scandium is increased cross-wafer thin film stress. For example, AlN thin film doped with about 5 atomic percent scandium may have a cross-wafer thin film stress ranging from about −700 MPa (e.g., at a center portion of the wafer) to about +300 MPa (e.g., at outer edges of the wafer), which is a cross-wafer thin film stress variation of approximately 1000 MPa. This stress variation can cause a 0.6 percent variation in the electromechanical coupling coefficient Kt², e.g., using the slope value of 0.0006 and the 1000 MPa variation. In comparison, a standard, undoped AlN thin film has a cross-wafer thin film stress variation of approximately 200 MPa. Accordingly, there is a need to reduce cross-wafer thin film stress, average stress, and cross-wafer coupling coefficient variation to improve wafer and product yield, particularly when doping piezoelectric thin film.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a perspective view of an illustrative model of a crystal structure of aluminum nitride (AlN).

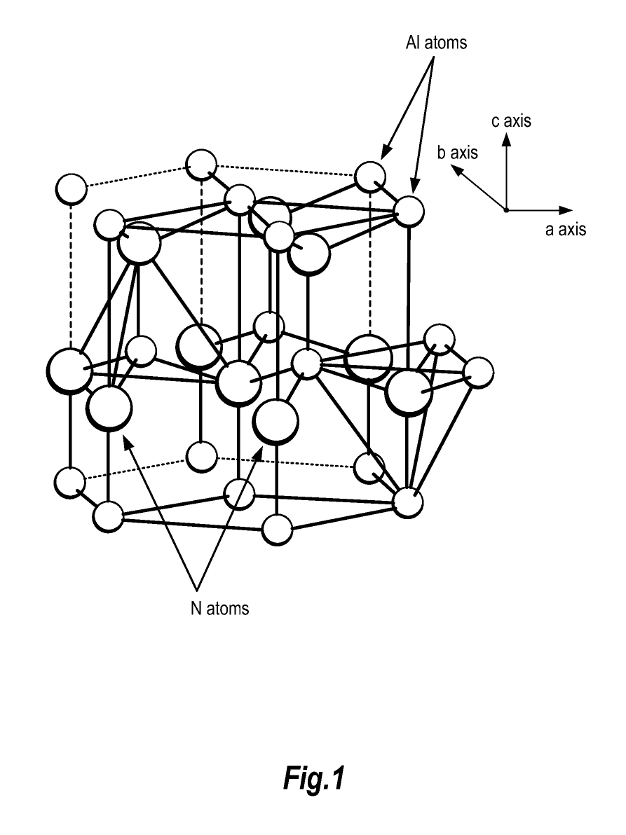

FIG. 2 is a simplified block diagram of a magnetron sputtering device for depositing a thin film of a material on a substrate, according to a representative embodiment.

FIG. 3 is a top perspective view of a magnetron in a magnetron sputtering device for depositing a thin film of a material on a substrate, according to a representative embodiment.

FIG. 4 is a flow diagram showing a method of sputtering material on a substrate using a magnetron sputtering device with an enhanced magnetic field strengths and power densities, according to a representative embodiment.

FIG. 5 is a table comparing cross-wafer stress and the piezoelectric coupling coefficients (Kt²) of a thin film deposited on a substrate using a magnetron sputtering device, according to representative embodiments.

### DETAILED DESCRIPTION

It is to be understood that the terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms “a”, “an” and “the” include both singular and plural referents, unless the context clearly dictates otherwise. Thus, for example, “a device” includes one device and plural devices. As used in the specification and appended claims, and in addition to their ordinary meanings, the terms “substantial” or “substantially” mean to within acceptable limits or degree. For example, “substantially cancelled” means that one skilled in the art would consider the cancellation to be acceptable. As used in the specification and the appended claims and in addition to its ordinary meaning, the term “approximately” or “about” means to within an acceptable limit or amount to one having ordinary skill in the art. For example, “approximately the same” means that one of ordinary skill in the art would consider the items being compared to be the same.

In the following detailed description, for purposes of explanation and not limitation, specific details are set forth in order to provide a thorough understanding of illustrative embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the illustrative embodiments. Such methods and apparatuses are clearly within the scope of the present teachings.

Generally, it is understood that the drawings and the various elements depicted therein are not drawn to scale. Further, relative terms, such as “above,” “below,” “top,” “bottom,” “upper” and “lower” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be below that element.

The present teachings relate generally to BAW resonator devices that may provide various filters (e.g., ladder filters), and other devices. Certain details BAW resonators, including FBARs, SMRs and resonator filters, materials thereof and their methods of fabrication may be found in one or more of the following commonly owned U.S. patents and patent applications: U.S. Pat. No. 6,107,721 to Lakin; U.S. Pat. Nos. 5,587,620, 5,873,153, 6,507,983, 6,384,697, 7,275,292 and 7,629,865 to Ruby et al.; U.S. Pat. No. 7,280,007 to Feng, et al.; U.S. Patent App. Pub. No. 2007/0205850 to Jamneala et al.; U.S. Pat. No. 7,388,454 to Ruby et al.; U.S. Patent App. Pub. No. 2010/0327697 to Choy et al.; and U.S. Patent App. Pub. No. 2010/0327994 to Choy et al. The entire contents of these patents and patent applications are hereby incorporated by reference. It is emphasized that the components, materials and method of fabrication described in these patents and patent applications are representative and other methods of fabrication and materials within the purview of one of ordinary skill in the art are contemplated.

Generally, according to various embodiments, sputtering of material onto a substrate using magnetron sputtering is enhanced by increasing the strength of a magnetic field generated by a magnetron of the magnetron sputtering device, and by increasing power density of power applied across the cathode and the anode of the magnetron sputtering device. For example, an upper magnetic field of the magnetron has a magnetic field strength greater than or equal to about 205 gauss, and a lower magnetic field of the magnetron has a magnetic field strength in a range of about −215 gauss to about −370 gauss. Also, the power density is in a range of about 20 W/cm² to about 60 W/cm². As a result, the cross-wafer thin film stress is substantially improved, average thin film stress is reduced, and the piezoelectric coupling coefficient (Kt²) of the thin film is more uniform.

Thus, according to a representative embodiment, a magnetron sputtering device for depositing a thin film of a compound material on a substrate includes a reaction chamber and a magnetron. The reaction chamber is configured to contain the substrate, a target and a sputtering gas. The magnetron is positioned adjacent the sputtering target and is configured to generate a magnetic field in the reaction chamber. The magnetron includes an upper base plate comprising horizontal upper base plate magnets and vertical upper base plate magnets, where the horizontal and vertical upper base plate magnets are configured to generate an upper magnetic field having a field strength of about 205 gauss; and a lower base plate comprising horizontal lower base plate magnets and vertical lower base plate magnets, where the horizontal and vertical lower base plate magnets are configured to generate a lower magnetic field having a magnetic field strength in less than −200 gauss. Application of power across an anode and a cathode of the magnetron creates plasma from the sputtering gas in the reaction chamber, the plasma sputtering atoms from the target, which are deposited on the substrate for forming the thin film of the compound material.

According to another representative embodiment, a method is provided for depositing a thin film of a compound material on a substrate using sputter deposition. The method includes providing the substrate on a cathode and a target on an anode in a reaction chamber of a magnetron sputtering device; generating a magnetic field in the reaction chamber using an enhanced magnetron of the magnetron sputtering device, the enhanced magnetron comprising an upper base plate configured to generate an upper magnetic field having a field strength of about 205 gauss and a lower base plate configured to generate a lower magnetic field having a field strength in a range of about −215 gauss to about −370 gauss; injecting a sputtering gas at low pressure into the reaction chamber; applying power across the anode and the cathode of the magnetron sputtering device to create plasma from the sputtering gas in the reaction chamber, ions from the plasma sputtering atoms of at least one element from the target, which are deposited on the substrate to form the thin film of the compound material. A power density of the power applied across the anode and the cathode is in a range of about 20 W/cm² to about 60 W/cm².

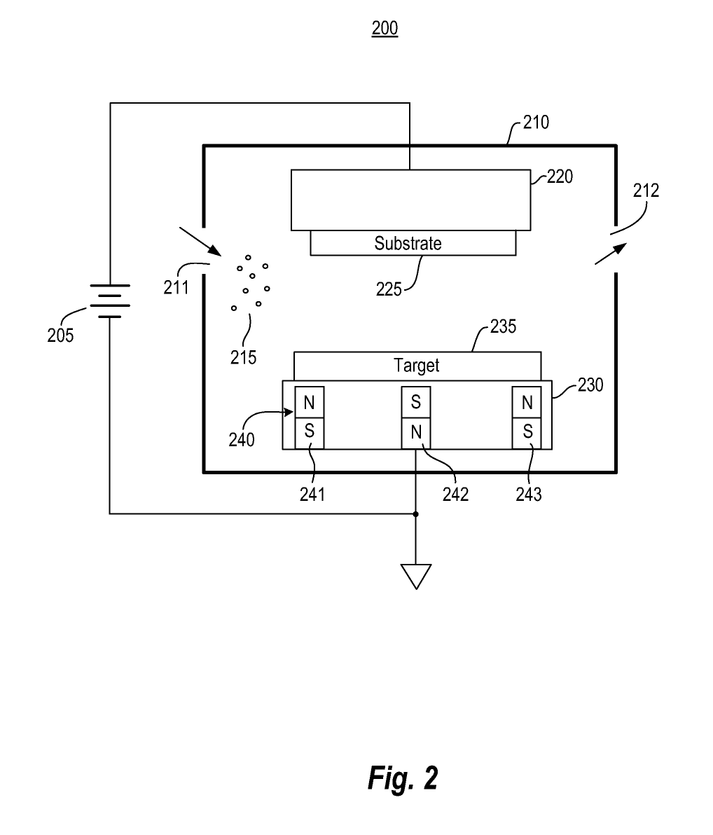

FIG. 2 is a simplified block diagram of a magnetron sputtering device for depositing a thin film of a compound material on a substrate, according to a representative embodiment.

Referring to FIG. 2, magnetron sputtering device 200 includes a reaction chamber 210 that contains a cathode 220 on which a (positively charged) substrate 225 is mounted, and an anode 230 on which a (negatively charged) sputtering target 235 is mounted. Power is applied across the cathode 220 and the anode 230 by DC voltage source 205. In various embodiments, power density of the power applied across the cathode 220 and the anode 230 is substantially increased over the power density of conventional sputtering devices. That is, the power density of the magnetron sputtering device 200 is in a range of about 20 W/cm² to about 60 W/cm². For example, in an embodiment, the power density of the magnetron sputtering device 200 applied across the cathode 220 and the anode 230 may be about 40 W/cm². In comparison, the power density used by a conventional magnetron sputtering device is typically less than about 20 W/cm², for example, although power density may vary depending on various factors, such as the type of equipment.

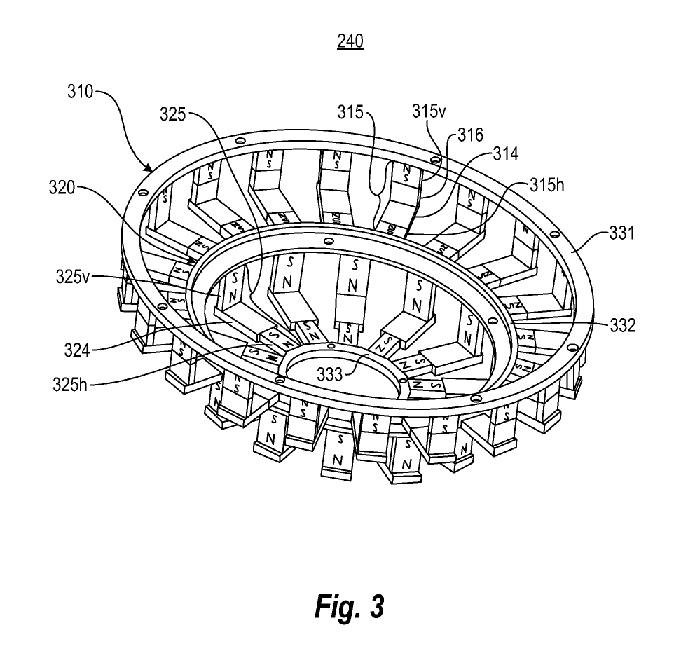

The reaction chamber 210 further contains a magnetron 240 positioned adjacent the sputtering target 235. The magnetron 240 is configured to generate an enhanced magnetic field in the reaction chamber 210 running substantially parallel to a top surface of the target 235. The magnetron 240 is generally indicated by the north (N)/south (S) pole arrangements 241 and 243 at the outer portions of the anode 230, and the oppositely polarized S/N pole arrangement 242 at an inner portion of the anode 230. Generally, the magnetic field directs plasma formed in the reaction chamber 210 toward the target 235, as discussed below. In the various embodiments, the magnetron 240 is enhanced in that it provides a substantially increased magnetic field strength as compared to conventional magnetrons, discussed below in detail with reference to FIG. 3.

The substrate 225 may be a chip or a wafer (to be subsequently separated into multiple chips). The substrate 225 may be formed of various materials, including materials compatible with semiconductor processes, such as silicon (Si), gallium arsenide (GaAs), indium phosphide (InP), or the like, which are useful for integrating connections and electronics. The target 235 likewise may be formed of various materials, depending on the desired composition of the resulting thin film. For example, the target 235 may be formed entirely of a single element, or may be a compound formed of a base element with one or more doping elements (dopants). For example, if the desired composition of the thin film to be formed on the substrate 225 is aluminum nitride (AlN), where the nitrogen (N) is provided as a reaction gas included in sputtering gas 215, as discussed below, the target 235 is formed entirely of aluminum (Al). If it is desired to sputter a thin film consisting of a compound of aluminum nitride (AlN) doped with a rare earth element, such as scandium (Sc), erbium (Er) or yttrium (Y), for example, the target 235 may be formed of aluminum and one or more rare earth elements in proportions substantially the same as those desired in the sputtered thin film. Alternatively, multiple targets may be provided, including the target 235 formed of a first material to be deposited as the thin film and another target (not shown) formed of a second material to be deposited as the thin film. The relative sizes of the multiple targets would correspond to the desired proportionate amounts of the materials in the sputtered thin film. Other rare earth elements include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), thulium (Tm), ytterbium (Yb) and lutetium (Lu), as known by one of ordinary skill in the art. The various embodiments contemplate incorporation of any rare earth elements. Further, other materials forming the substrate 225 and the target 235 may be incorporated without departing from the scope of the present teachings.

In an embodiment, the target 235 may be a previously formed alloy of materials provided in the desired proportions. For example, the target 235 may be an alloy formed of aluminum and one or more of rare earth element(s) already mixed in with the aluminum in the desired proportions. In an alternative embodiment, the target 235 may be a composite target formed of a block of a base element containing inserts or plugs of doping element(s). For example, the doping element(s) may be introduced by drilling one or more holes in the base element and inserting plugs of the doping element(s) into the respective holes in the desired proportions. For example, the target 235 may be formed substantially of a block of aluminum as the base element, and plugs of doping elements (e.g., scandium, erbium and/or yttrium) may be insertable into holes previously formed in the block of aluminum. The percentage of each of the doping element(s) in the finished thin film corresponds to the collective volume of that element inserted into one or more respective holes, which displaces a corresponding volume of the base element. Examples of doping with rare earth elements are provided by Grannen et al. in U.S. patent application Ser. No. 13/662,460 (filed Oct. 27, 2012) and Bradley et al. in U.S. patent application Ser. No. 13/662,425 (filed Oct. 27, 2012), the entire contents of which are hereby incorporated by reference in their entireties.

The size and number of holes, as well as the amount and type of the doping element filling each of the holes, may be determined on a case-by-case basis, depending on the desired percentages of the doping elements. For example, the holes may be drilled partially or entirely through the base element of the target 235 in the desired sizes and numbers in various patterns. Similarly, in alternative embodiments, the dopants may be added to the base element of the target 235 in the desired proportions using various alternative types of insertions, without departing from the scope of the present teachings. For example, full or partial rings formed of the dopants, respectively, may be inlaid in the target 235. The number, width, depth and circumference of each ring may be adjusted to provide the desired proportion of each particular element. The structures and techniques for providing an appropriate sputtering target 235 may vary to provide unique benefits for any particular situation or to meet application specific design requirements of various implementations, without departing from the scope of the present teachings, as would be apparent to one skilled in the art.

In operation, sputtering gas 215 enters input 211 and exits output 212 of the reaction chamber 210. The sputtering gas 215 includes at least an inert gas of neutral atoms, such as argon (Ar). Generally, power (voltage) is applied across the anode 230 and the cathode 220 by the DC voltage source 205 to create an electric field within the reaction chamber 210, causing the sputtering gas 215 to form plasma. That is, the electric field ionizes the neutral atoms of the inert gas. The resulting ions from the plasma bombard the negatively charged target 235 on the anode 230. Collisions between the ions and the surface of the target 235 cause atoms and electrons to be ejected (sputtered) from the target 235. A portion of the ejected atoms (or elements) travel through the reaction chamber 210 and are deposited on the surface of the substrate 225, gradually building up a layer of sputtered material to form the thin film. Meanwhile, the ejected electrons are held close to the surface of the target 235 by the magnetic field (magnetic envelop) generated by magnetron 240. The presence of these trapped electrons generally increases arrival energy and plasma density, which improves sputter deposition rates. Notably, the sputtering gas 215 may also include one or more reaction gases, such as nitrogen in the case of sputtering a thin film of AlN. Atoms of the reaction gas are also deposited on the surface of the substrate 225, along with the atoms ejected from the target 235. Of course, different mixes and types of inert and/or reaction gases may be included without departing from the scope of the present teachings.

FIG. 3 is a top perspective view of an enhanced magnetron in the magnetron sputtering device shown in FIG. 2, according to a representative embodiment.

Referring to FIG. 3, magnetron 240 includes an upper base plate 310 and a lower base plate 320. In the depicted embodiment, the magnetron 240 is substantially circular in shape. Thus, in addition to being above the lower base plate 320, the upper base plate 310 is formed concentrically around the outer circumference of the lower base plate 320.

Each of the upper and lower base plates 310 and 320 include multiple magnets for generating the magnetic field. More particularly, the upper base plate 310 includes multiple upper base plate magnets (indicated by representative upper base plate magnet 315) arranged circumferentially around the upper base plate 310, where the upper base plate magnets are connected between an upper ring 331 and a middle ring 332 of the magnetron 240. In the depicted embodiment, each of the upper base plate magnets (315) has a north/south pole arrangement, and comprises a horizontal upper base plate magnet (e.g., representative horizontal upper base plate magnet 315h) and a vertical upper base plate magnet (e.g., representative vertical upper base plate magnet 315v). The lower base plate 320 includes multiple lower base plate magnets (indicated by representative lower base plate magnet 325) arranged circumferentially around the lower base plate 320, where the lower base plate magnets are connected between the middle ring 332 and a lower ring 333 of the magnetron 240. In the depicted embodiment, each of the lower base plate magnets (325) has a south/north pole arrangement, and comprises a horizontal lower base plate magnet (e.g., representative horizontal lower base plate magnet 325h) and a vertical lower base plate magnet (e.g., representative vertical lower base plate magnet 325v). An opening is formed by the lower ring 333 at the center of the lower base plate 320, in which the anode 230 and the target 235 (not shown in FIG. 3) are situated.

In more detail, referring to the representative upper base plate magnet 315, the horizontal upper base plate magnet 315h has a south pole connected to the middle ring 332 and a north pole connected to a horizontal pole piece 314, while the vertical upper base plate magnet 315v has a south pole connected to a vertical pole piece 316 and a north pole connected to the upper ring 331. Referring to the representative lower base plate magnet 325, the horizontal lower base plate magnet 325h has a north pole connected to the lower ring 333 and a south pole connected to a horizontal pole piece 324, while the vertical lower base plate magnet 325v has a north pole connected to the horizontal pole piece 314 and a south pole connected to the middle ring 332. Of course, other arrangements of upper lower base plate magnets may be included, without departing from the scope of the present teachings.

The upper and lower base plate magnets of the magnetron 240 collectively generate a magnetic field that runs substantially parallel to the top surface of the target 235 in FIG. 2, as mentioned above. For purposes of illustration, the magnetic field may be described in terms of combining an upper magnetic field generated by the upper base plate magnets (315) and a lower magnetic field generated by the lower base plate magnets (325). According to various embodiments, the upper magnetic field has a magnetic field strength greater than or equal to about 205 gauss, and the lower magnetic field has a magnetic field strength less than or equal to about −210 gauss. For example, the upper base plate magnets (315) may be configured to generate an upper magnetic field having a magnetic field strength greater than or equal to about 205 gauss and the lower base plate magnets (325) may be configured to generate a lower magnetic field having a magnetic field strength in a range of about −215 gauss to about −370 gauss. In comparison, a conventional magnetron having a similar arrangement of upper and lower base plates generates upper and lower magnetic fields having magnetic field strengths of about 200 gauss and about −200 gauss, respectively.

In order increase the magnetic field strengths of the upper and lower magnetic fields of the magnetron 240, the dimensions of one or more of the horizontal and vertical upper base plate magnets 315h and 315v and the horizontal and vertical lower base plate magnets 325h and 325v, respectively, are altered. For example, in an embodiment, each of the horizontal and vertical upper base plate magnets 315h and 315v has a length of about 0.49 inch, a width of about 0.75 inch and a thickness of about 0.19 inch, and each of the horizontal and vertical lower base plate magnets 325h and 325v has a length of about 0.98 inch, a width of about 0.75 inch and a thickness of about 0.19 inch. This results in an upper magnetic filed strength of about 205 gauss and a lower magnetic field strength of about −230 gauss.

In other embodiments, the dimensions of the horizontal and vertical upper base plate magnets 315h and 315v may be different from one another, and/or the dimensions of the horizontal and vertical lower base plate magnets 325h and 325v may be different from one another. For example, in an illustrative embodiment, each of the horizontal and vertical upper base plate magnets 315h and 315v has a length of about 0.49 inch, a width of about 0.75 inch and a thickness of about 0.19 inch, each of the horizontal lower base plate magnets 325h has a length of about 0.98 inch, a width of about 0.75 inch and a thickness of about 0.19 inch, and each of the vertical lower base plate magnets 325v has a length of about 0.98 inch, a width of about 0.75 inch and a thickness of about 0.25 inch. This results in an upper magnetic filed strength of about 205 gauss and a lower magnetic field strength of about −250 gauss.

Also, in another illustrative embodiment, each of the horizontal and vertical upper base plate magnets 315h and 315v has a length of about 0.49 inch, a width of about 0.75 inch and a thickness of about 0.19 inch, each of the horizontal lower base plate magnets 325h has a length of about 2.48 inches, a width of about 0.75 inch and a thickness of about 0.19 inch, and each of the vertical lower base plate magnets 325v has a length of about 0.98 inch, a width of about 0.75 inch and a thickness of about 0.19 inch. This results in an upper magnetic filed strength of about 205 gauss and a lower magnetic field strength of about −300 gauss. Of course, various other combinations of dimensions may be incorporated without departing from the scope of the present teachings.

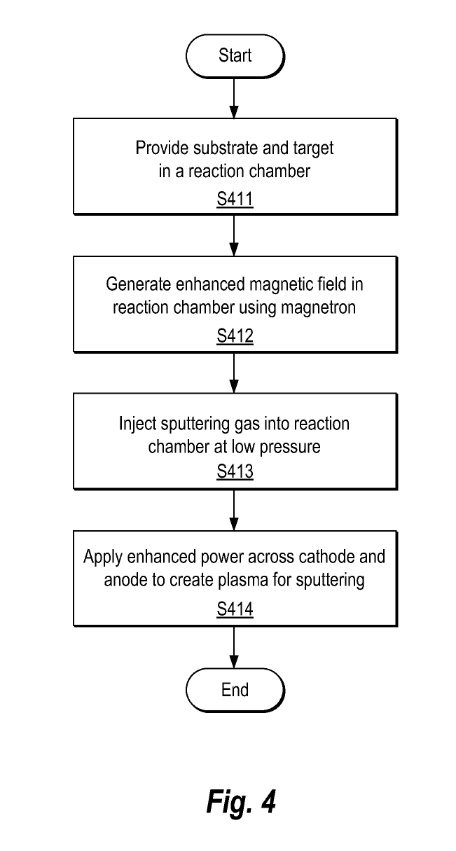

FIG. 4 is a flow diagram showing a method of depositing a thin film of compound material on a substrate using sputter deposition, according to a representative embodiment.

Referring to FIG. 4, various items required for depositing a thin film of compound material on a substrate using a magnetron sputtering device are provided in block S411. For example, substrate 225 may be applied to cathode 220 and target 235 may be applied to anode 230 in reaction chamber 210 of magnetron sputtering device 200. As discussed above, the target 235 may be a single element (e.g., aluminum) or a combination of elements (e.g., aluminum doped with one or more rare earth elements, such as scandium, erbium and yittrium). For example, the target 235 may be a preformed alloy of aluminum and at least one rare earth element in desired proportions. Alternatively, the target 235 may be a block of aluminum having at least one hole into which one or more plugs of at least one rare earth element is insertable. The amount of aluminum in the aluminum block and the total amount of rare earth element(s) inserted as plug(s) into the aluminum block are provided in the desired proportions.

In block S412, a magnetic field is generated in the reaction chamber 210, for example, using magnetron 240 of the magnetron sputtering device 200. The magnetron 240 is enhanced in that it generates a greater magnetic field strength than a conventional magnetron. That is, the magnetron 240 includes upper base plate 310 configured to generate an upper magnetic field and lower base plate 320, surrounded by the upper base plate 310, configured to generate a lower magnetic field. In an embodiment, the upper magnetic field has a field strength of about 205 gauss, and the lower magnetic field has a field strength in a range of about −215 gauss to about −370 gauss, for example. In comparison, upper and lower magnetic fields applied in a conventional magnetron sputtering process have field strengths of about 200 gauss and about −200 gauss, respectively.

Sputtering gas 215 is injected into the reaction chamber 210 at low pressure in block S413. For example, the sputtering gas 215 may be maintained at a pressure of about 2 mTorr to about 5 mTorr in the reaction chamber 210. As discussed above, the sputtering gas 215 contained in the reaction chamber 210 may include an inert gas (e.g., argon), or an inert gas (e.g., argon) combined with a reaction gas (e.g., nitrogen). In the latter scenario, at least a portion of the reaction gas is deposited on the substrate 225 along with the at least one element from the target 235 for forming the thin film of the compound material on the substrate 225.

In block S414, power is applied across the cathode 220 and the anode 230 of the magnetron sputtering device 200 to create plasma from the sputtering gas 215 injected into the reaction chamber 210 in block S413. The plasma comprises ions that bombard the target 235, causing atoms of at least one element (along with electrons) to be ejected from the target 235. At least some of the ejected atoms are sputtered onto the substrate 225 to form the thin film of the compound material. The power applied across the cathode 220 and the anode 230 of the magnetron sputtering device 200 is enhanced over power applied in a conventional method, in that power density of the power applied across the cathode 220 and the anode 230 is in a range of about 20 W/cm² to about 60 W/cm². In an embodiment, the applied power may have a power density is about 40 W/cm², for example.

The magnetic field generated in block S412 generally runs substantially parallel to the top surface of the sputtering target 235. Accordingly, electrons ejected from the target 235 in response to the ion bombardment are held close to the surface of the target 235 by the magnetic field generated by magnetron 240. The presence of these trapped electrons generally increases arrival energy and plasma density, which improves sputter deposition rates, as mentioned above.

Increasing the magnetic field strengths of the upper and lower magnetic fields generated by the magnetron 240, as well as increasing the sputter power density of the power applied across the cathode 220 and the anode 230 and flows of the sputtering gas 215, produces an improved cross-wafer stress profile, and thus a much better electromechanical coupling coefficient Kt² variation and attendant wafer yield. In an experiment performed for purposes of illustration, a conventional magnetron sputtering process for providing an ScAlN thin film (with about 5 atomic percent scandium) produced a cross-wafer thin film stress range of approximately 800 MPa, with roughly two thirds of the wafer having stress values between about zero and −500 MPa. The magnetron sputtering process for providing an ScAlN thin film (with about 5 atomic percent scandium), using enhanced magnetic field strength and power density according to a representative embodiment, produced a cross-wafer thin film stress range of approximately 500 MPa, with two thirds of the wafer having thin film stress values between about −100 and −400 MPa. Optimization of the magnetic field thus reduced the overall average thin film stress and the thin film stress range, as well as the standard deviation of the thin film stress.

As discussed above, due to dependence of the electromechanical coupling coefficient Kt² on the observed thin film stress, the spread of the electromechanical coupling coefficient Kt² (coupling coefficient spread) across the wafer is reduced when using the enhanced magnetic field strength and power density according to representative embodiments, as compared to conventional magnetic field strength and power density.

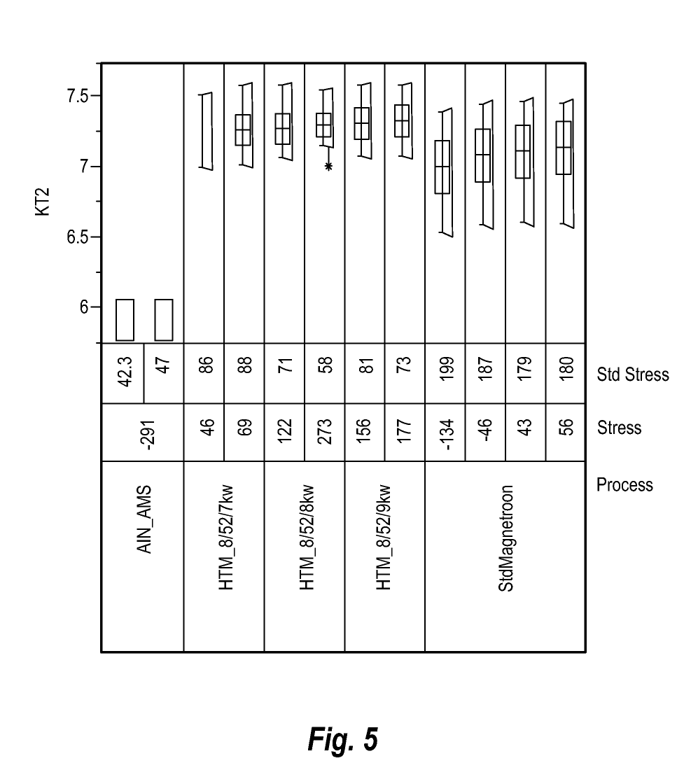

FIG. 5 is a table comparing cross-wafer stress and the electromechanical coupling coefficients Kt² of a thin film deposited on a substrate using a magnetron sputtering device, according to representative embodiments.

Referring to FIG. 5, five process groups of data are presented. The top process group ALN_AMS refers to standard undoped AlN thin film deposited according to a standard sputtering process using a conventional magnetron sputtering device. The bottom process group StdMagnetron refers to AlN thin film doped with about 5 atomic percent scandium, to provide a ScAlN thin film, deposited according to a standard sputtering process using a conventional magnetron sputtering device. The three middle process groups HTM_{—}8/52/7 kw, HTM_{—}8/52/8 kw and HTM_{—}8/52/9 kw refer to AlN thin film doped with about 5 atomic percent scandium, to provide a ScAlN thin films, which are provided according to enhanced sputtering processes and magnetron sputtering devices, according to representative embodiments. HTM_{—}8/52/7 kw, HTM_{—}8/52/8 kw and HTM_{—}8/52/9 kw correspond to enhanced upper magnetic fields of about 205 gauss, lower magnetic fields of about −230 gauss, and applied powers of about 7 kW, 8 KW and 9 kW, respectively (corresponding to power densities of about 43, 49, and 56, respectively). In addition, FIG. 5 provides resulting average thin film stress across the wafer (“Stress”) and standard deviation of thin film stress (“StdStress”) provided for each of the five process groups. By way of example, the process group HTM 8/52/9 KW includes two wafers having average stresses of 156 and 177 MPa and standard deviations of 81 and 73 MPa, respectively.

It is apparent from FIG. 5 that application of the enhanced magnetic fields and power densities are effective in reducing the cross-wafer electromechanical coupling coefficient Kt² variation by almost 50 percent, as indicated by the horizontal bars under “KT2.” For example, referring again to the process group HTM 8/52/9 KW, the cross-wafer electromechanical coupling coefficient Kt² ranges from about 7.0 to about 7.5 for a variation of about 0.5. In comparison, referring to each of the StdMagnetron process groups, the cross-wafer electromechanical coupling coefficients Kt² range from about 6.5 to about 7.5 for a variation of about 10. Thus, the process group HTM 8/52/9 KW demonstrates a roughly 50 percent improvement. In addition, this effect can be realized at the different sputtering power densities. By utilizing the combined effect of the increased magnetic field strength and power densities, thin films of doped piezoelectric material are formed with lower and more uniform thin film stress and electromechanical coupling coefficients.

In alternative embodiments, piezoelectric thin films doped with one or more rare earth elements may be sputtered in resonator stacks of various other types of resonator devices, without departing from the scope of the present teachings. For example, a piezoelectric layer doped with one or more rare earth elements may be sputtered in resonator stacks of a solidly mounted resonator (SMR) device, a stacked bulk acoustic resonator (SBAR) device, a double bulk acoustic resonator (DBAR) device, or a coupled resonator filter (CRF) device.

One of ordinary skill in the art would appreciate that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A magnetron sputtering device for depositing a thin film of a material on a substrate, the device comprising:
a reaction chamber configured to contain the substrate, a target and a sputtering gas; and
a magnetron positioned adjacent the sputtering target and configured to generate a magnetic field in the reaction chamber, the magnetron comprising:
an upper base plate comprising a plurality of horizontal upper base plate magnets and a plurality of vertical upper base plate magnets, wherein the horizontal and vertical upper base plate magnets are configured to generate an upper magnetic field having a field strength of about 205 gauss; and
a lower base plate comprising a plurality of horizontal lower base plate magnets and a plurality of vertical lower base plate magnets, wherein the horizontal and vertical lower base plate magnets are configured to generate a lower magnetic field having a magnetic field strength in less than −200 gauss,
wherein application of power across an anode and a cathode of the magnetron creates plasma from the sputtering gas in the reaction chamber, the plasma sputtering atoms from the target, which are deposited on the substrate for forming the thin film of the material.

2. The device of claim 1, wherein a power density of the power applied across the anode and the cathode is in a range of about 20 W/cm2 to about 60 W/cm2.

3. The device of claim 2, wherein the power density of the power applied across the anode and the cathode is about 40 W/cm2.

4. The device of claim 1, wherein the horizontal and vertical lower base plate magnets are configured to generate the lower magnetic field to have a magnetic field strength in a range of about −215 gauss to about −370 gauss.

5. The device of claim 1, wherein the sputtering gas comprises an inert gas and a reaction gas, a least a portion of the reaction gas being deposited on the substrate for forming the thin film of the material.

6. The device of claim 5, wherein the inert gas is argon, the reaction gas in nitrogen.

7. The device of claim 6, wherein the target comprises aluminum and at least one rare earth element.

8. The device of claim 7, wherein the least one rare earth element is scandium.

9. The device of claim 1, wherein each of the horizontal and vertical upper base plate magnets has a length of about 0.49 inch, a width of about 0.75 inch and a thickness of about 0.19 inch.

10. The device of claim 9, wherein each of the horizontal and vertical lower base plate magnets has a length of about 0.98 inch, a width of about 0.75 inch and a thickness of about 0.19 inch.

11. The device of claim 9, wherein each of the horizontal lower base plate magnets has a length of about 0.98 inch, a width of about 0.75 inch and a thickness of about 0.19 inch, and each of the vertical lower base plate magnets has a length of about 0.98 inch, a width of about 0.75 inch and a thickness of about 0.25 inch.

12. The device of claim 9, wherein each of the horizontal lower base plate magnets has a length of about 2.48 inches, a width of about 0.75 inch and a thickness of about 0.19 inch, and each of the vertical lower base plate magnets has a length of about 0.98 inch, a width of about 0.75 inch and a thickness of about 0.19 inch.

13. A method of depositing a thin film of a material on a substrate using sputter deposition, the method comprising:
providing the substrate on a cathode and a target on an anode in a reaction chamber of a magnetron sputtering device;
generating a magnetic field in the reaction chamber using an enhanced magnetron of the magnetron sputtering device, the enhanced magnetron comprising an upper base plate configured to generate an upper magnetic field having a field strength of about 205 gauss and a lower base plate configured to generate a lower magnetic field having a field strength in a range of about −215 gauss to about −370 gauss;
injecting a sputtering gas at low pressure into the reaction chamber; and
applying power across the anode and the cathode of the magnetron sputtering device to create plasma from the sputtering gas in the reaction chamber, ions from the plasma sputtering atoms of at least one element from the target, which are deposited on the substrate to form the thin film of the material,
wherein a power density of the power applied across the anode and the cathode is in a range of about 20 W/cm² to about 60 W/cm².

14. The method of claim 13, wherein the sputtering gas comprises an inert gas and a reaction gas, a least a portion of the reaction gas being deposited on the substrate along with the at least one element from the target for forming the thin film of the material.

15. The method of claim 14, wherein the inert gas is argon, the reaction gas in nitrogen, and wherein the target comprises aluminum and at least one rare earth element.

16. The method of claim 14, wherein the at least one element from the target and the reaction gas are deposited on the substrate in proportionate amounts.

17. The method of claim 13, wherein the magnetic field directs the plasma toward the target.

18. The method of claim 13, wherein power density is about 40 W/cm².

19. The method of claim 15, wherein the target comprises a preformed alloy of aluminum and scandium in desired proportions.

20. The method of claim 15, wherein the target comprises a block of aluminum having at least one hole and at least one plug of scandium insertable in the at least one hole, the aluminum and scandium being in desired proportions.
